(19) United States
(12) Patent Application Publication
(10) Pub. No.: US 2022/0140132 A1
(43) Pub. Date: May 5, 2022

(54) PASSIVATION STRUCTURES FOR SEMICONDUCTOR DEVICES

(71) Applicant: Cree, Inc., Durham, NC (US)

(72) Inventors: Edward Robert Van Brunt, Raleigh, NC (US); Joe W. McPherson, Plano, TX (US); Thomas E. Harrington, III, Carrollton, TX (US); Sei-Hyung Ryu, Cary, NC (US); Brett Hull, Raleigh, NC (US); In-Hwan Ji, Cary, NC (US)

(21) Appl. No.: 17/088,686

(22) Filed: Nov. 4, 2020

(51) Int. Cl. H01L 29/78; H01L 29/16; H01L 29/06; H01L 29/10; H01L 29/40; H01L 23/31

(52) U.S. Cl. CPC H01L 29/7811; H01L 29/1608; H01L 29/0623; H01L 23/3192; H01L 29/402; H01L 23/3171; H01L 29/1095

(57) ABSTRACT

Semiconductor devices, and more particularly passivation structures for semiconductor devices are disclosed. A semiconductor device may include an active region, an edge termination region that is arranged along a perimeter of the active region, and a passivation structure that may form a die seal along the edge termination region. The passivation structure may include a number of passivation layers in an arrangement that improves mechanical strength and adhesion of the passivation structure along the edge termination region. An interface formed by at least one of the passivation layers may be provided with a pattern that serves to more evenly distribute forces related to thermal expansion and contraction during power cycling, thereby reducing cracking and delamination in the passivation structure. A patterned layer may be at least partially embedded in the passivation structure in an arrangement that forms the corresponding pattern in overlying portions of the passivation structure.

### FIELD OF THE DISCLOSURE

The present disclosure is related to semiconductor devices, and in particular to passivation structures for semiconductor devices.

### BACKGROUND

Semiconductor devices such as transistors and diodes are ubiquitous in modern electronic devices. Wide bandgap semiconductor material systems such as gallium nitride (GaN) and silicon carbide (SiC) are being increasingly utilized in semiconductor devices to push the boundaries of device performance in areas such as switching speed, power handling capability, and thermal conductivity. Examples include individual devices such as metal-oxide-semiconductor field-effect transistors (MOSFETs), insulated gate bipolar transistors (IGBTs), Schottky barrier diodes, PiN diodes, high electron mobility transistors (HEMTs), and integrated circuits such as monolithic microwave integrated circuits (MMICs) that include one or more individual devices.

Semiconductor devices are typically formed in an active region of a semiconductor die. In semiconductor die manufactured to support high voltages and currents, concentration of electric fields can interfere with the proper operation thereof. Concentration of electric fields is especially problematic at edges of the semiconductor die. Accordingly, an edge termination region surrounds the active region about a perimeter of the semiconductor die to reduce electric fields at the edges of the die. Without an edge termination region, electric fields would concentrate at the edges of the die and cause the performance of the die to suffer. For example, the breakdown voltage, leakage current, and/or reliability of the die may be significantly reduced. Specifically, the die may suffer from leakage current under reverse bias when subject to thermal stress (e.g., temperatures greater than 150° C.) that may be associated with higher operating voltages. While several edge termination structures have been proposed for reducing the concentration of electric fields at the edges of a die, many of the proposed structures may not be suitable for withstanding thermal shock and power cycling associated with higher temperature and higher voltage operating conditions.

The art continues to seek improved edge termination structures for semiconductor devices capable of overcoming challenges associated with conventional semiconductor devices.

### SUMMARY

The present disclosure is related to semiconductor devices, and in particular to passivation structures for semiconductor devices. A semiconductor device may include an active region, an edge termination region that is arranged along a perimeter of the active region, and a passivation structure that may form a die seal along the edge termination region. The passivation structure may include a number of passivation layers in an arrangement that improves mechanical strength and adhesion of the passivation structure along the edge termination region. An interface formed by at least one of the passivation layers may be provided with a pattern that serves to more evenly distribute forces related to thermal expansion and contraction during power cycling, thereby reducing cracking and delamination in the passivation structure. The pattern may include a number of protrusions and recesses in at least one of the passivation layers. A patterned layer may be at least partially embedded in the passivation structure to form the pattern in overlying portions of the passivation structure.

In one aspect, a semiconductor device comprises: a drift region; an active region comprising a portion of the drift region; an edge termination region in the drift region and arranged along a perimeter of the active region; a passivation structure on the edge termination region; and a patterned layer that is formed within the passivation structure. In certain embodiments, the patterned layer is embedded within the passivation structure. In certain embodiments, the patterned layer comprises polysilicon. The passivation structure may comprise a first passivation layer on the drift region and a second passivation layer that is on the first passivation layer. In certain embodiments, the patterned layer is arranged between the first passivation layer and the second passivation layer. In certain embodiments, the second passivation layer forms at least one protrusion that is registered with at least one portion of the patterned layer.

The passivation structure of the semiconductor device may further comprise a third passivation layer that is on the second passivation layer and wherein the at least one protrusion of the second passivation layer extends into the third passivation layer. In certain embodiments, the at least one protrusion comprises a plurality of protrusions and a top surface of the third passivation layer is planar in at least some portions of the passivation structure. The passivation structure may further comprise a fourth passivation layer that is on the third passivation layer, and the top surface of the third passivation structure forms an interface with the fourth passivation layer. In certain embodiments, the edge termination region further comprises a plurality of guard rings in the drift region; and the at least one portion of the patterned layer is registered with an individual guard ring of the plurality of guard rings. In certain embodiments, the at least one portion of the patterned layer is registered with at least two individual guard rings of the plurality of guard rings. The at least one guard ring of the plurality of the guard rings may be devoid of a directly overlying portion of the patterned layer. In certain embodiments, the at least one guard ring of the plurality of guard rings is arranged closer to the active region than any other guard ring of the plurality of guard rings. In certain embodiments, the at least one portion of the patterned layer forms a field plate in the passivation structure. The at least one portion of the patterned layer may be registered with the individual guard ring of the plurality of guard rings in a vertically offset position. In certain embodiments, the patterned layer is arranged on the first passivation layer and the patterned layer further extends past a sidewall of the first passivation layer in a direction towards an outside edge of the edge termination region.

In certain embodiments, the patterned layer forms at least one continuous ring around a perimeter of the active region. In certain embodiments, the patterned layer forms at least one segmented ring around a perimeter of the active region. The at least one segmented ring may comprise a first segmented ring and a second segmented ring of the patterned layer; and ring segments of the first segmented ring are arranged in laterally offset positions relative to ring segments of the second segmented ring.

In certain embodiments, the drift region comprises silicon carbide (SiC). In certain embodiments, the active region comprises a SiC metal-oxide-semiconductor field-effect-transistor (MOSFET).

In another aspect, a semiconductor device comprises: a drift region; an active region comprising a portion of the drift region; an edge termination region in the drift region and arranged along a perimeter of the active region; and a passivation structure on the edge termination region, wherein a passivation layer of the passivation structure forms at least one protrusion that partially extends into an additional passivation layer of the passivation structure. The at least one protrusion may form at least one protrusion ring around a perimeter of the active region. In certain embodiments, the at least one protrusion ring is continuous around the perimeter of the active region. In certain embodiments, the at least one protrusion ring is segmented around the perimeter of the active region.

In certain embodiments, the at least one protrusion comprises a plurality of protrusions; the passivation layer forms a plurality of recesses in between adjacent protrusions of the plurality of protrusions; and portions of the additional passivation layer extend into each recess of the plurality of recesses. In certain embodiments, at least a portion of a top surface of the additional passivation layer that is opposite the plurality of recesses is planar. In certain embodiments, the plurality of recesses comprises a first recess and a second recess; the first recess comprises a width that is larger than a width of the second recess; and the first recess is arranged closer to an outside edge of the edge termination region than the second recess.

The semiconductor device may further comprise a patterned layer in the passivation structure and the patterned layer is registered with the at least one protrusion. In certain embodiments, the patterned layer comprises polysilicon. In certain embodiments, the at least one protrusion comprises a plurality of protrusions; and a discontinuous portion of the patterned layer is registered with each protrusion of the plurality of protrusions. In certain embodiments, the edge termination region comprises a plurality of guard rings in the drift region; and a discontinuous portion of the patterned layer is registered with an individual guard ring of the plurality of guard rings.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view illustration of an exemplary semiconductor device according to the present disclosure.

FIG. 1B illustrates a cross-sectional view of a portion of the semiconductor device of FIG. 1A for embodiments where the semiconductor device includes a MOSFET.

FIG. 2A is a partial cross-sectional view of a semiconductor device that is similar to the semiconductor device of FIG. 1B and provides a more detailed view of the edge termination region.

FIG. 2B is a top view illustration of the semiconductor device of FIG. 2A.

FIG. 3 is a partial cross-sectional view of a semiconductor device that is similar to the semiconductor device of FIG. 2A and further includes an arrangement of the passivation layers in the edge termination region that provides improved structural stability.

FIG. 4 is a partial cross-sectional view of a semiconductor device that is similar to the semiconductor device of FIG. 3, but wherein individual portions of the patterned layer are registered with more than one of the guard rings.

FIG. 5 is a partial cross-sectional view of a semiconductor device that is similar to the semiconductor device of FIG. 3, but wherein at least one guard ring does not have a portion of the patterned layer registered with it in an overlying arrangement.

FIG. 6 is a partial cross-sectional view of a semiconductor device that is similar to the semiconductor device of FIG. 3, but wherein at least one guard ring is electrically connected to portion of the patterned layer through the first passivation layer.

FIG. 7 is a partial cross-sectional view of a semiconductor device that is similar to the semiconductor device of FIG. 3, but wherein portions of the patterned layer are registered with underlying guard rings in a vertically offset manner.

FIG. 8A is a top view of a portion of a semiconductor device where the patterned layer forms one or more continuous rings around a perimeter of the active region according to principles of the present disclosure.

FIG. 8B is a top view of a portion of a semiconductor device where the patterned layer forms one or more segmented rings around a perimeter of the active region according to principles of the present disclosure.

FIG. 9 is a partial cross-sectional view of a semiconductor device that is similar to the semiconductor device of FIG. 3, but wherein the patterned layer forms a ring at a perimeter of the first passivation layer.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure is related to semiconductor devices, and in particular to passivation structures for semiconductor devices. A semiconductor device may include an active region, an edge termination region that is arranged along a perimeter of the active region, and a passivation structure that may form a die seal along the edge termination region. The passivation structure may include a number of passivation layers in an arrangement that improves mechanical strength and adhesion of the passivation structure along the edge termination region. An interface formed by at least one of the passivation layers may be provided with a pattern that serves to more evenly distribute forces related to thermal expansion and contraction during power cycling, thereby reducing cracking and delamination in the passivation structure. The pattern may include a number of protrusions and recesses in at least one of the passivation layers. A patterned layer may be at least partially embedded in the passivation structure to form the pattern in overlying portions of the passivation structure.

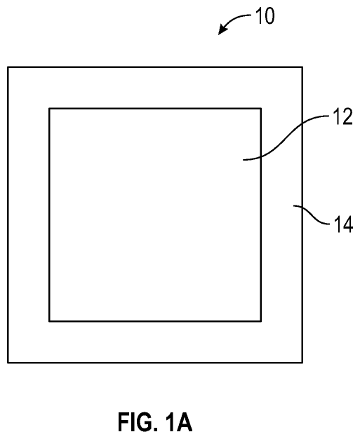

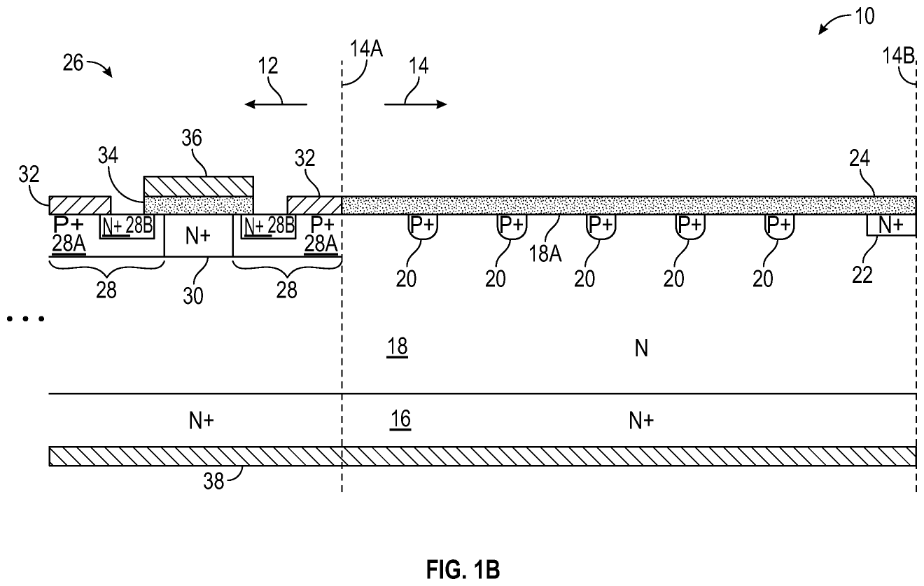

FIG. 1A is a top view illustration of an exemplary semiconductor device 10 according to the present disclosure. The semiconductor device 10 includes an active region 12 and an edge termination region 14 surrounding the active region 12 about a perimeter of the semiconductor device 10. Depending on the particular application, the active region 12 may include one or more semiconductor devices or semiconductor device cells formed therein, such as one or more metal-oxide-semiconductor field-effect transistors (MOSFETs), diodes, Schottky diodes, junction barrier Schottky (JBS) diodes, PiN diodes, and insulated gate bipolar transistors (IGBTs), among others. The semiconductor device 10 may embody wide bandgap semiconductor devices, for example silicon carbide (SiC)-based devices. The edge termination region 14 is configured to reduce a concentration of an electric field at the edges of the semiconductor device 10 in order to improve the performance thereof. For example, the edge termination region 14 may increase a breakdown voltage of the semiconductor device 10 and decrease a leakage current of the semiconductor device 10 over time, as discussed in detail below. By way of example, the edge termination region 14 may include one or more guard rings, a junction termination extension (JTE), and combinations thereof.

FIG. 1B illustrates a cross-sectional view of a portion of the semiconductor device 10 of FIG. 1A for embodiments where the semiconductor device 10 includes a MOSFET. While an exemplary MOSFET is described, the principles of the present disclosure are applicable to other semiconductor devices listed above, including diodes, Schottky diodes, JBS diodes, PiN diodes, and IGBTs, among others. The semiconductor device 10 includes a substrate 16 and a drift region 18 on the substrate 16. The drift region 18 may embody one or more drift layers of a wide bandgap semiconductor material, for example SiC. An inside edge 14A of the edge termination region 14 is indicated by a vertical dashed line to delineate the edge termination region 14 from the active region 12. An outside edge 14B of the edge termination region 14 may correspond with a peripheral edge of the semiconductor device 10. In the edge termination region 14, a number of guard rings 20 are provided in the drift region 18. Specifically, the guard rings 20 are provided adjacent or even directly adjacent a top surface 18A of the drift region 18 opposite the substrate 16. The guard rings 20 may be formed by ion implantation and the implants used may include aluminum (Al), boron (B), or any other suitable p-type dopant when the drift region 18 is configured as an n-type layer. Each guard ring 20 forms a sub-region in the edge termination region 14 that has a doping type that is opposite a doping type of the drift region 18. In the present example, the drift region 18 is an n-type layer while the guard rings 20 are p-type sub-regions. However, the principles of the present disclosure apply equally to devices with opposite polarity configurations where the doping types as illustrated in FIG. 1B may be reversed. For illustrative purposes, five guard rings 20 are illustrated in FIG. 1B. In various embodiments, the number of guard rings 20 may be five or more, or ten or more, or twenty or more, or in a range from five to twenty, or in a range from ten to twenty, depending on the application.

When a voltage is supported by the drift region 18, electric field concentration at the outside edge 14B of the edge termination region 14 tends to be substantially higher than at the inside edge 14A of the edge termination region 14. In certain embodiments, a surface depletion protection region 22 may also be provided in the drift region 18 at the outside edge 14B of the edge termination region 14. The surface depletion protection region 22 may have the same doping type as the drift region 18 but a higher doping concentration than that of the drift region 18. In this manner, the surface depletion protection region 22 may prevent depletion at the top surface 18A of the drift region 18 in order to further improve the performance of the semiconductor device 10. In certain embodiments, the surface depletion protection region 22 is provided by implantation. A passivation layer 24 may be provided on the top surface 18A of the drift region 18 opposite the substrate 16 to passivate the top surface 18A of the drift region 18. The passivation layer 24 may embody one or more layers of insulating materials of any suitable material, for example one or more layers of oxide and/or nitride-based dielectric layers. In certain embodiments, the passivation layer 24 may embody a multilayer structure that includes one or more of a field oxide layer, one or more intermetal dielectric layers, and a top insulating layer.

The substrate 16 may have a doping concentration between 1×10¹⁷ cm⁻³ and 1×10²⁰ cm⁻³. In various embodiments, the doping concentration of the substrate 16 may be provided at any subrange between 1×10¹⁷ cm⁻³ and 1×10²⁰ cm⁻³. For example, the doping concentration of the substrate 16 may be between 1×10¹⁸ cm⁻³ and 1×10²⁰ cm⁻³, between 1×10¹⁹ cm⁻³ and 1×10²⁰ cm⁻³, between 1×10¹⁷ cm⁻³ and 1×10¹⁹ cm⁻³, between 1×10¹⁷ cm⁻³ and 1×10¹⁸ cm⁻³, and between 1×10¹⁸ cm⁻³ and 1×10¹⁹ cm⁻³.

The drift region 18 may have a doping concentration between 1×10¹⁴ cm⁻³ and 1×10¹⁸ cm⁻³. In various embodiments, the doping concentration of the drift region 18 may be provided at any subrange between 1×10¹⁴ cm⁻³ and 1×10¹⁸ cm⁻³. For example, the doping concentration of the drift region 18 may be between 1×10¹⁵ cm⁻³ and 1×10¹⁸ cm⁻³, between 1×10¹⁶ cm⁻³ and 1×10¹⁸ cm⁻³, between 1×10¹⁷ cm⁻³ and 1×10¹⁸ cm⁻³, between 1×10¹⁴ cm⁻³ and 1×10¹⁷ cm⁻³, between 1×10¹⁴ cm⁻³ and 1×10¹⁶ cm⁻³, between 1×10¹⁴ cm⁻³ and 1×10¹⁵ cm⁻³, between 1×10¹⁵ cm⁻³ and 1×10¹⁷ cm⁻³, between 1×10¹⁵ cm⁻³ and 1×10¹⁶ cm⁻³, and between 1×10¹⁶ cm⁻³ and 1×10¹⁷ cm⁻³. The surface depletion protection region 22 may have a doping concentration that is higher than the doping concentration of the drift region 18. In various embodiments, the surface depletion protection region 22 may have a doping concentration in a range from two times to 10⁵ times the doping concentration of the drift region 18.

The guard rings 20 may have a doping concentration between 5×10¹⁶ cm⁻³ and 1×10²¹ cm⁻³. In various embodiments, the doping concentration of the guard rings 20 may be provided at any subrange between 5×10¹⁶ cm⁻³ and 1×10²¹ cm⁻³. For example, the doping concentration of the guard rings 20 may be between 5×10¹⁸ cm⁻³ and 1×10²¹ cm⁻³, between 5×10¹⁹ cm⁻³ and 1×10²¹ cm⁻³, between 5×10²⁰ cm⁻³ and 1×10²¹ cm⁻³, between 5×10¹⁶ cm⁻³ and 1×10²⁰ cm⁻³, between 5×10¹⁶ cm⁻³ and 1×10¹⁹ cm⁻³, and between 5×10¹⁶ cm⁻³ and 1×10²⁰ cm⁻³.

As discussed above, the active region 12 may include one or more semiconductor devices. In the example of FIG. 1B, the active region 12 includes at least one MOSFET cell 26, for example a SiC-based MOSFET where the drift region 18 embodies one or more layers of SiC. The MOSFET cell 26 includes the substrate 16 and the drift region 18. A number of junction implants 28 are provided in the drift region 18, and specifically in the top surface 18A of the drift region 18 opposite the substrate 16. The junction implants 28 include a first well region 28A having a doping type that is opposite that of the drift region 18 and a second well region 28B having a doping type that is the same as the drift region 18. The junction implants 28 are separated from one another by a JFET region 30. The JFET region 30 has the same doping type as that of the drift region 18 and a higher doping concentration than that of the drift region 18. A source contact 32 is provided over each one of the junction implants 28 on the top surface 18A of the drift region 18 opposite the substrate 16 such that the source contact 32 contacts a portion of the first well region 28A and the second well region 28B. A gate oxide layer 34, which may embody other insulating materials for other semiconductor devices, is provided on the top surface 18A of the drift region 18 opposite the substrate 16 over the JFET region 30 and a portion of each one of the junction implants 28 such that the gate oxide layer 34 partially overlaps each one of the second well regions 28B. A gate contact 36 is provided on the gate oxide layer 34. A drain contact 38 is provided on a surface of the substrate 16 opposite the drift region 18. The MOSFET cell 26 may be tiled across the active region 12 or tiled in a desired pattern with one or more other semiconductor devices (e.g., diodes) to provide a desired functionality.

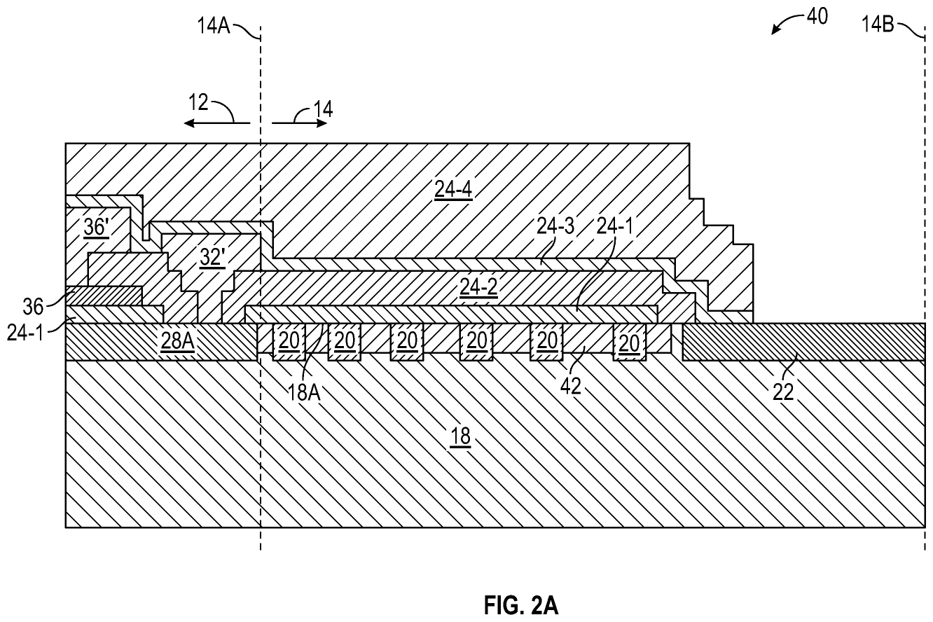

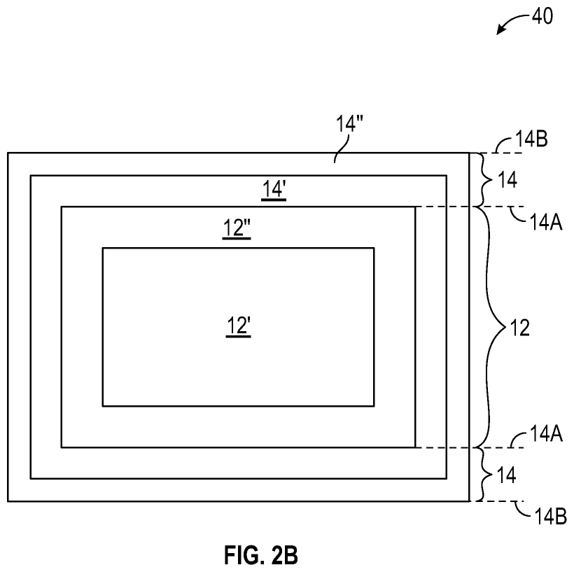

FIG. 2A is a partial cross-sectional view of a semiconductor device 40 that is similar to the semiconductor device 10 of FIG. 1B and provides a more detailed view of the edge termination region 14. The edge termination region 14 may include a surface charge compensation region 42 that is formed between the guard rings 20 and at the top surface 18A of the drift region 18. The surface charge compensation region 42 may be formed by ion implantation and may have a doping type that is opposite a doping type of the drift region 18. In this manner, the surface charge compensation region 42 has a same doping type as the guard rings 20, but with a lower doping concentration than the guard rings 20. In the present example, the drift region 18 is an n-type layer while the surface charge compensation region 42 and the guard rings 20 have p-type doping. However, the principles of the present disclosure apply equally to devices with opposite polarity configurations. The surface charge compensation region 42 may have a thickness relative to the top surface 18A of the drift region 18 that is the same or less than a corresponding thickness of the guard rings 20. The surface charge compensation region 42 may reduce sensitivity of the guard rings 20 to surface charges at interfaces between a first passivation layer 24-1 and the drift region 18.

As illustrated, the first passivation layer 24-1 may be formed on the top surface 18A of the drift region 18 and the guard rings 20. The first passivation layer 24-1 may comprise an oxide layer or other insulation layer that is formed in the same fabrication step and comprises a same material as the gate oxide layer 34 of FIG. 1B. In certain embodiments, the first passivation layer 24-1 may have a thickness that is greater than a thickness of the gate oxide layer 34 of FIG. 1B. For example, the thickness of the first passivation layer 24-1 may be from 2 times to 100 times the thickness of the gate oxide layer 34 of FIG. 1B. For MOSFET applications, the first passivation layer 24-1 may comprise silicon dioxide. In other embodiments, the first passivation layer 24-1 comprises a different dielectric material than the gate oxide layer 34 of FIG. 1B. In various applications, the first passivation layer 24-1 may be referred to as a field oxide for the semiconductor device 40. A second passivation layer 24-2 may be provided on the first passivation layer 24-1. In certain embodiments, the second passivation layer 24-2 may comprise one or more dielectric layers, which may include combinations of silicon dioxide layers and silicon nitride layers, that serve as inter-metal dielectrics to electrically insulate metal interconnect lines and may also serve as inter-level dielectrics to electrically insulate polysilicon gates and lines from metal interconnect lines. In the semiconductor device 40, one or more portions of the second passivation layer 24-2 in the active region 12 serve to at least partially define and insulate a gate interconnect 36′ and a source interconnect 32′. In this cross-section of FIG. 2A, the source contact (32 of FIG. 1B) is not visible as the source interconnect 32′ is configured as a runner or a bus that electrically connects with the source contact (32 of FIG. 1B) in a different portion of the semiconductor device 40. As illustrated, the second passivation layer 24-2 may overlap the first passivation layer 24-1 in a direction toward the outside edge 14B and contact the top surface 18A of the drift region 18 and the surface depletion protection region 22. A third passivation layer 24-3 may be provided over the second passivation layer 24-2, the gate interconnect 36′ and the source interconnect 32′. The third passivation layer 24-3 may comprise one or more dielectric layers, which may include combinations of silicon dioxide layers and silicon nitride layers, that can provide a diffusion and/or moisture barrier for the underlying portions of the semiconductor device 40. The third passivation layer 24-3 may overlap the second passivation layer 24-2 in a direction toward the outside edge 14B and contact the top surface 18A of the drift region 18 and the surface depletion protection region 22. Finally, a fourth passivation layer 24-4 may be provided on the third passivation layer 24-3. In certain embodiments, the fourth passivation layer 24-4 may comprise a material with chemical, mechanical, and high temperature stability, for example a polyimide that may provide a scratch-resistant coating for the semiconductor device 40. Additionally, the passivation layers 24-1 to 24-4 may not extend entirely to the outside edge 14B of the edge termination region 14 in order to provide clearance for a saw or scribe street when the semiconductor device 40 is singulated. One or more combinations of the passivation layers 24-1 to 24-4 may be referred to as a passivation structure and/or a die seal for the semiconductor device 40. In the present example, the drift region 18 is an n-type layer while the guard rings 20 are p-type sub-regions, although reverse polarity configurations are also applicable to the present disclosure.

When the semiconductor device 40 is electrically activated, an electric potential from the backside of the drift region 18 (e.g., the drain contact 38 of FIG. 1B) tends to concentrate electric fields along the edge termination region 14. When the semiconductor device 40 is in a blocking mode, voltages supported by the drift region 18 tend to be higher at the outside edge 14B and decrease in a direction toward the inside edge 14A with each of the guard rings 20. In this regard, higher associated operating temperatures can introduce thermal stress in the edge termination region 14 and promote structural failures in one or more of the passivation layers 24-1 to 24-4. For example, thermal shock and power cycling during operating conditions and/or qualification testing can lead to delamination and/or cracking of one or more of the passivation layers 24-1 to 24-4, thereby causing catastrophic device failure. In particular, delamination and/or cracking may be more problematic when adjacent ones of the passivation layers 24-1 to 24-4 that have dissimilar materials and/or different materials properties are subjected to thermal expansion and contraction during power cycling. Dissimilar materials properties may include a mismatched coefficient of thermal expansion (CTE), among others. By way of example, delamination and/or cracking can occur at an interface between the second passivation layer 24-2 and the third passivation layer 24-3 in arrangements where the second passivation layer 24-2 comprises silicon dioxide and third passivation comprises silicon nitride. The likelihood of such structural failures may be higher when the interface between the second passivation layer 24-2 and the third passivation layer 24-3 is substantially planar throughout a majority of the edge termination region 14. In this regard, forces related to thermal stress will be exerted in-plane and along continuous planar portions of the second and third passivation layers 24-2, 24-3. This can be especially problematic when the semiconductor device 40 is scaled with larger device sizes suitable for handling higher operating powers in applications such as automotive drivetrains.

FIG. 2B is a top view illustration of the semiconductor device 40 of FIG. 2A. FIG. 2B is provided to generally illustrate the relative location of the edge termination region 14 relative to the active region 12. The active region 12 may include an inner region 12′ and an outer region 12″. The inner region 12′, which may be referred to as a device core, may include the source contacts 32 and gate contacts 36 as illustrated in FIG. 1B, and the outer region 12″ may include the gate interconnect 36′ and the source interconnect 32′ as illustrated in FIG. 2A. The edge termination region 14 may include an inner region 14′ and an outer region 14″. The outer region 14″ is defined where the passivation layers 24-1 to 24-4 of FIG. 2A are not present, thereby forming part of the saw or scribe street as previously described.

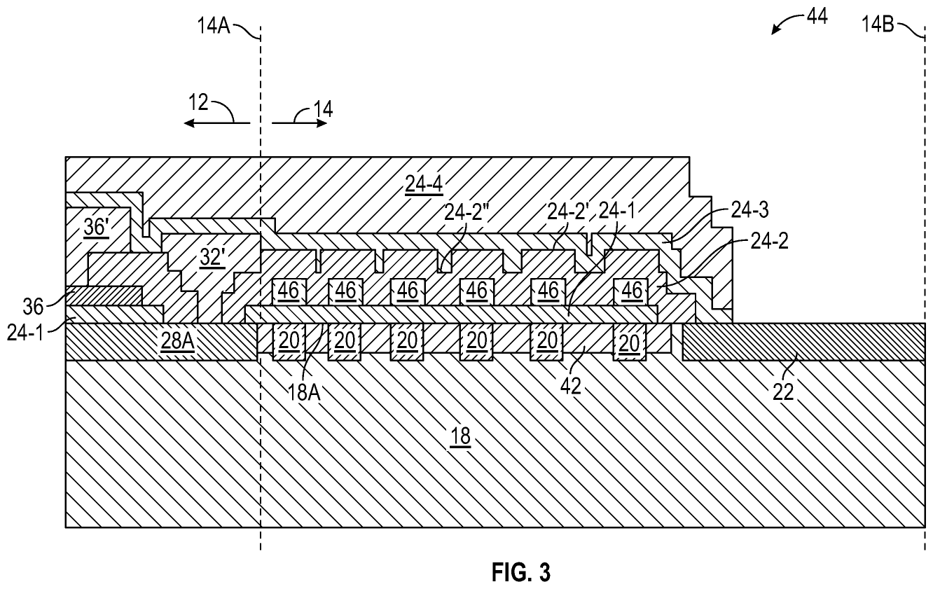

FIG. 3 is a partial cross-sectional view of a semiconductor device 44 that is similar to the semiconductor device 40 of FIG. 2A and further includes an arrangement of the passivation layers 24-1 to 24-4 in the edge termination region 14 that provides improved structural stability. Any combination of the passivation layers 24-1 to 24-4 may be referred to as a passivation structure or a die seal for the semiconductor device 44. As illustrated, a top surface of the second passivation layer 24-2 that is opposite the first passivation layer 24-1 is formed with a number of protrusions 24-2′ and a number of corresponding recesses 24-2″ that are formed between adjacent ones of the protrusions 24-2′ to form a nonplanar or patterned interface with the third passivation layer 24-3. Portions of the third passivation layer 24-3 are formed within the recesses 24-2″ and over the protrusions 24-2′ to cover the second passivation layer 24-2. In this manner, the interface between the second passivation layer 24-2 and the third passivation layer 24-3 is subdivided into a series of adjacent and nonplanar segments that may serve to improve adhesion by breaking up forces related to thermal expansion and contraction during power cycling, thereby reducing cracking and delamination. The protrusions 24-2′ and the recesses 24-2″ may alternate in one or more lateral directions in a corrugated pattern. Since the edge termination region 14 may be provided around a perimeter of the active region 12 as illustrated in FIG. 2B, the protrusions 24-2′ and the recesses 24-2″ may embody protrusion rings and recessed rings that either partially or entirely surround the active region 12. For illustrative purposes the protrusions 24-2′ and the recesses 24-2″ are represented with squared features, however the protrusions 24-2′ and the recesses 24-2″ can have rounded, curved, and/or angled features, and boundaries that are represented with straight lines may have some irregularities.

In certain embodiments, a patterned layer 46 is provided on the first passivation layer 24-1 to promote formation of the protrusions 24-2′ and the recesses 24-2″ of the second passivation layer 24-2 in a corresponding pattern. In particular, discontinuous portions of the patterned layer 46 may be registered with one or more of the guard rings 20. When the second passivation layer 24-2 is formed on the first passivation layer and the patterned layer 46, portions of the second passivation layer 24-2 may form in a conformal manner over the patterned layer 46 to form the protrusions 24-2′. Additionally, other portions of the second passivation layer 24-2 are conformal on the first passivation layer 24-1 and within spaces formed between discontinuous portions of the patterned layer 46 to form the recesses 24-2″. As illustrated, the patterned layer 46 may be embedded, or partially embedded, within the second passivation layer 24-2, but for the portions of the patterned layer 46 that are in contact with the first passivation layer 24-1. In this manner, the patterned layer 46 may be embedded within the passivation structure formed by one or more of the passivation layers 24-1 to 24-4. The third passivation layer 24-3 may then be formed on the second passivation layer 24-2 in a manner that fills the recesses 24-2″ and covers the protrusions 24-2′. In certain embodiments, relative spacings between adjacent ones of the discontinuous portions of the patterned layer 46 may increase in a direction from the inside edge 14A of the edge termination region 14 to the outside edge 14B. In this manner, relative widths of the recesses 24-2″ may also increase from the inside edge 14A to the outside edge 14B such that recesses 24-2″ that are closer to the outside edge 14B are wider and filled with more of the third passivation layer 24-3 than recesses 24-2″ that are closer to the inside edge 14A. Such configurations may provide improved structural stability near the outside edge 14B where cracking and delamination may be more likely to occur. As illustrated, depending on the widths of the recesses 24-2′, the third passivation layer 24-3 may form with a planar top surface or planar interface with the fourth passivation layer 24-4 as illustrated over the portions of the patterned layer 46 that are closest to the active region 12. The third passivation layer 24-3 may also form with a top surface or interface with the fourth passivation layer 24-4 that is conformal to the underlying second passivation layer 24-2 as illustrated over the portions of the patterned layer 46 that are closest to the outside edge 14B. For example, the closest recess 24-2″ to the outside edge 14B is wide enough that a portion of the fourth passivation layer 24-4 extends or protrudes downward into portions of the third passivation layer 24-3 that are conformal to this recess 24-2″. In certain embodiments, the shape of the top surface of the third passivation layer 24-3 may further be controlled by adjusting an overall thickness of the third passivation layer 24-3 where an increased thickness would generally promote a more planar top surface and a decreased thickness would generally promote a more conformal top surface. In this manner, the pattern of the protrusions 24-2′ may not extend entirely through the passivation structure (e.g., all four passivation layers 24-1 to 24-4 in FIG. 3). Rather the pattern of the protrusions 24-2′ may eventually be smoothed over by overlying passivation layers (e.g., portions of 24-3 and 24-4 in FIG. 3) depending on one or more of the spacing of the patterned layer 46 and/or relative thicknesses of one or more of the overlying passivation layers 24-3, 24-4. In other embodiments, the spacing of the patterned layer 46 and/or the relative thicknesses of one or more of the overlying passivation layers 24-3, 24-4 may be arranged to allow the pattern of the protrusions 24-2′ to form all the way through the passivation structure (24-1 to 24-4). In still further embodiments, the pattern of the protrusions 24-2′ may be smoothed over only in certain portions of the semiconductor device 44. For example, the third passivation layer 24-3 smooths over portions of the pattern of protrusions 24-2′ near the inside edge 14A while other portions of the third passivation layer 24-3 are conformal near the outside edge 14B in FIG. 3.

The patterned layer 46 may comprise any material that is non-reactive with the first passivation layer 24-1 and the second passivation layer 24-2. In certain embodiments, the patterned layer 46 comprises a material that exhibits improved mechanical stability under thermal stress than the surrounding passivation layers 24-1 to 24-3. For example, the patterned layer 46 may have a higher elastic modulus than any of the passivation layers 24-1 to 24-4, in order to resist deformation under thermal cycling. In this manner, the patterned layer 46 may also reduce expansion and contraction of the second passivation layer 24-2. In certain embodiments, the patterned layer 46 may comprise polysilicon that may be doped n-type or p-type and in other embodiments, the patterned layer 46 may comprise polysilicon that is low-doped or undoped. In certain embodiments, the patterned layer 46 may comprise a same material as the gate contact 36 (e.g., polysilicon), thereby providing the advantage of forming the patterned layer 46 in a same fabrication step as the gate contact 36. In other embodiments, the patterned layer 46 may comprise other materials, such as other passivation or dielectric materials, and metal layers. In still further embodiments, the patterned layer 46 may embody a multiple layer structure including multiple layers of any of above-described materials and combinations thereof.

The patterned layer 46 may comprise electrically conductive materials or electrically non-conductive materials depending on the embodiment. When the patterned layer 46 comprises conductive materials, for example doped polysilicon or metal layers, each discontinuous portion of the patterned layer 46 may be registered with one of the guard rings 20 as illustrated in FIG. 3. In this manner, the discontinuous portions of the patterned layer 46 may be capacitively coupled to corresponding guard rings 20 to stabilize electric fields within the semiconductor device 44. In certain embodiments, discontinuous portions of the patterned layer 46 may have widths as measured in a parallel direction to the drift region 18 that are either the same or smaller than a width of the corresponding guard ring 20. In other embodiments, discontinuous portions of the patterned layer 46 may have widths that are larger than widths of corresponding guard rings 20. In still further embodiments, widths of the discontinuous portions of the patterned layer 46 can be smaller, larger, or the same in different locations relative to the outside edge 14B of the edge termination region 14. The widths of discontinuous portions of the patterned layer 46 relative to widths of corresponding guard rings 20 may be tailored for electric fields in a particular application. As described above, the guard rings 20 may be formed as rings around the perimeter of the active region 12. In certain embodiments, the discontinuous portions of the patterned layer 46 form corresponding rings of the patterned layer 46 that are also formed around the perimeter of the active region 12.

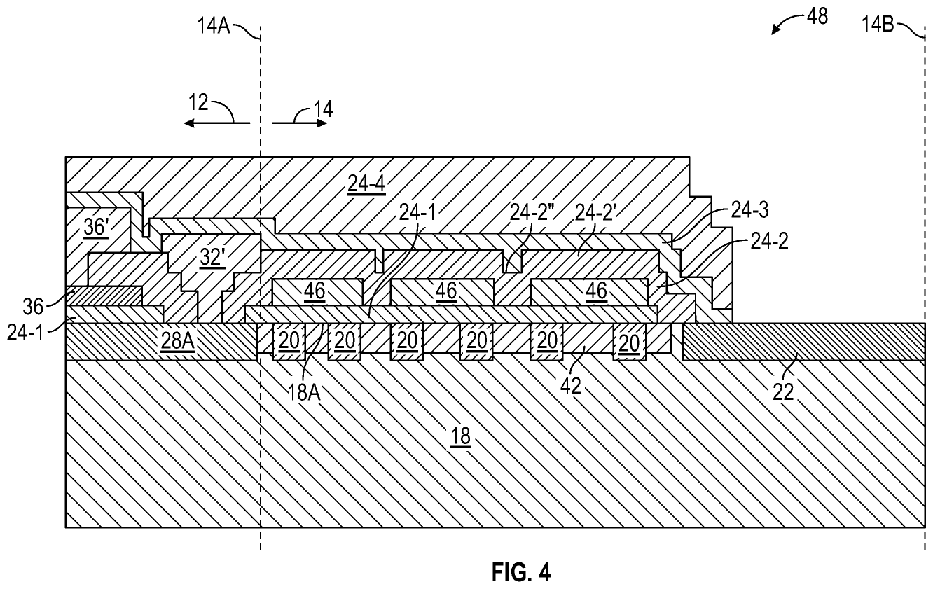

FIG. 4 is a partial cross-sectional view of a semiconductor device 48 that is similar to the semiconductor device 44 of FIG. 3, but wherein individual portions of the patterned layer 46 are registered with more than one of the guard rings 20. In FIG. 4, a discontinuous portion of the patterned layer 46 is arranged to extend over two individual and adjacent guard rings 20. In further embodiments, a discontinuous portion of the patterned layer 46 may be arranged to extend over more than two individual guard rings 20 without deviating from the principles of the present disclosure. As illustrated, a spacing between adjacent guard rings 20 may progressively increase in a direction from the inside edge 14A toward the outside edge 14B of the edge termination region 14.

Accordingly, widths of individual discontinuous portions of the patterned layer 46 and corresponding recesses 24-2″ of the second passivation layer 24-2 may also increase in a direction toward the outside edge 14B. As previously described, the patterned layer 46 may comprise electrically conductive or electrically nonconductive materials. For electrically conductive materials, the patterned layer 46 may be registered with multiple guard rings 20 to tailor electric fields. For electrically nonconductive materials, the patterned layer 46 may be provided across portions of the drift region 18 that are between guard rings 20 with minimal impact on electric fields of the semiconductor device 48. In certain embodiments, portions of the patterned layer 46 may be provided as described for FIG. 3 in combination with other portions of the patterned layer 46 as described for FIG. 4, depending on the electric field requirements of a particular application.

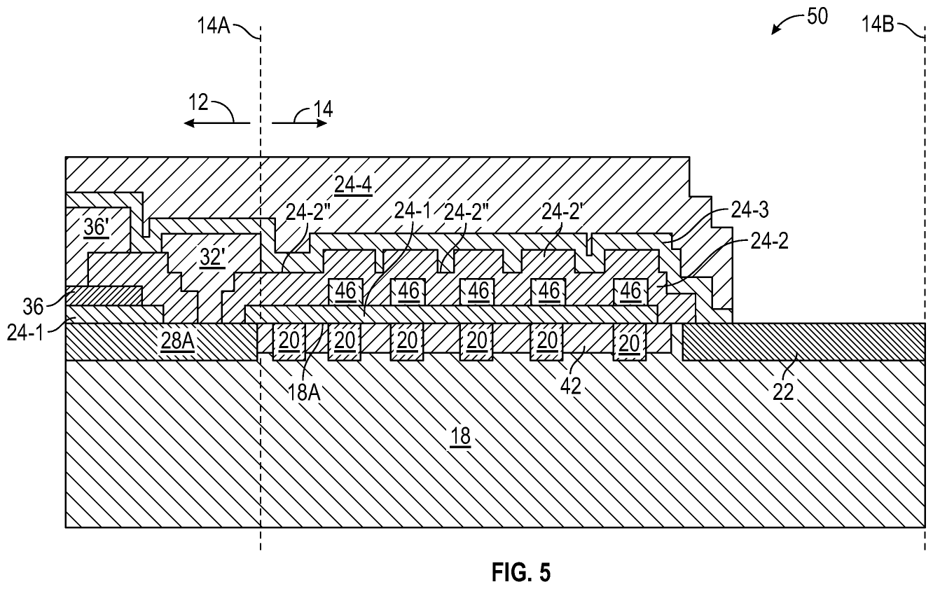

FIG. 5 is a partial cross-sectional view of a semiconductor device 50 that is similar to the semiconductor device 44 of FIG. 3, but wherein at least one guard ring 20 does not have a portion of the patterned layer 46 registered with it in an overlying arrangement. As illustrated, no portion of the patterned layer 46 is registered with the guard ring 20 that is arranged closest to the active region 12. In certain arrangements, particularly when the patterned layer 46 comprises an electrically conductive material, having portions of the patterned layer 46 arranged too close to the active region 12 may cause dielectric weakness or dielectric breakdown near the source interconnect 32′. In this regard, the patterned layer 46 may not be provided directly over one or more of the guard rings 20 that are arranged closest to the active region 12. In such an arrangement, the recess 24-2″ that is closest to the source interconnect 32′ may have a width that is larger than others of the recesses 24-2″ while widths of the other recesses 24-2″ may then progressively increase in a direction toward the outside edge 14B as previously described. Having a larger width recess 24-2″ closer to the active region 12 may serve to further enhance mechanical strength of the passivation structure in combination with the other protrusions 24-2′ and recesses 24-2″. In other embodiments, the patterned layer 46 may not be arranged over other guard rings 20 provide different patterns of the protrusions 24-2′ and recesses 24-2″. For example, the patterned layer 46 may only be provided over every other guard ring 20 to provide larger widths of the recesses 24-2″ between protrusions 24-2′. Such alternative arrangements may also be utilized to provide different electric filed patterns for the semiconductor device 50. In certain embodiments, portions of the patterned layer 46 in the semiconductor device 50 may also be provided as described above for FIG. 4, depending on the electric field requirements of a particular application.

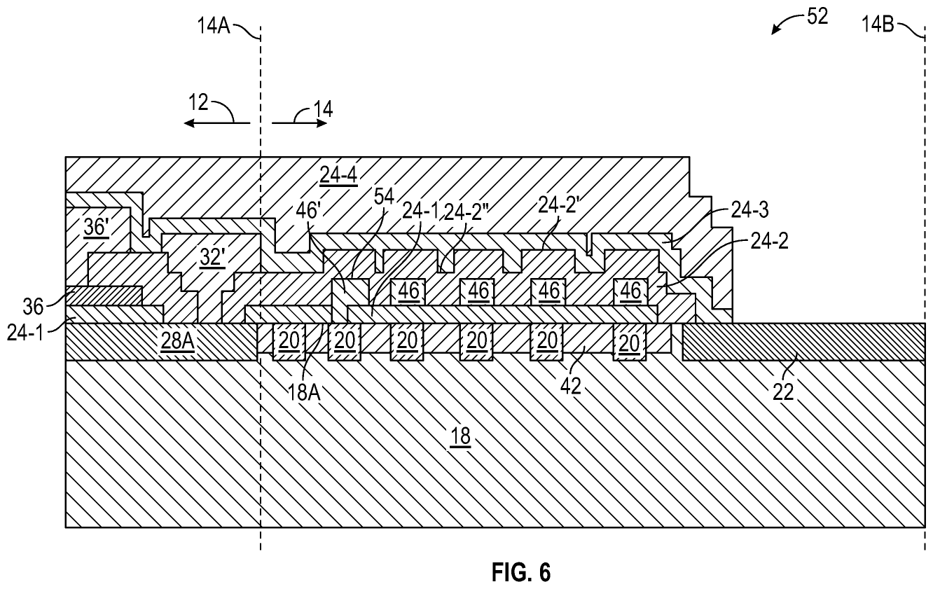

FIG. 6 is a partial cross-sectional view of a semiconductor device 52 that is similar to the semiconductor device 44 of FIG. 3, but wherein at least one guard ring 20 is electrically connected to portion of the patterned layer 46 through the first passivation layer 24-1. In FIG. 6, a portion 46′ of the patterned layer 46 that is closest to the active region 12 is electrically connected to the underlying guard ring 20 through an opening that is formed in the first passivation layer 24-1. Additionally, the portion 46′ of the patterned layer 46 extends over the passivation layer 24-1 to form a field plate 54 that is electrically connected to the underlying guard ring 20 and that is otherwise surrounded by the passivation layers 24-1, 21-2. In other embodiments, the field plate 54 may not be directly electrically connected with the corresponding guard ring 20 such that the first passivation layer 24-1 extends completely between the field plate 54 and the guard ring 20. Dimensions of the resulting field plate 54 may be determined to tune the electric field profile along the edge termination region 14 for improved efficiency. Since the field plate 54 is registered with the underlying guard ring 20, the field plate 54 may form a continuous field plate ring or a segmented field plate ring around the active region 12. Depending on the application, one or more of the other portions of the patterned layer 46 may also form field plates or filed plate rings that are registered with corresponding underlying guard rings 20. In further embodiments, one or more of the field plates 54 may extend over adjacent ones of the guard rings 20. As illustrated in FIG. 6, no portion of the patterned layer 46 is provided over the guard ring 20 closest to the active region 12 as described for FIG. 5. In other embodiments, portions of the patterned layer 46 in the semiconductor device 52 may also be provided as described for FIG. 3 and/or FIG. 4 in combination with FIG. 6, depending on the electric field requirements of a particular application.

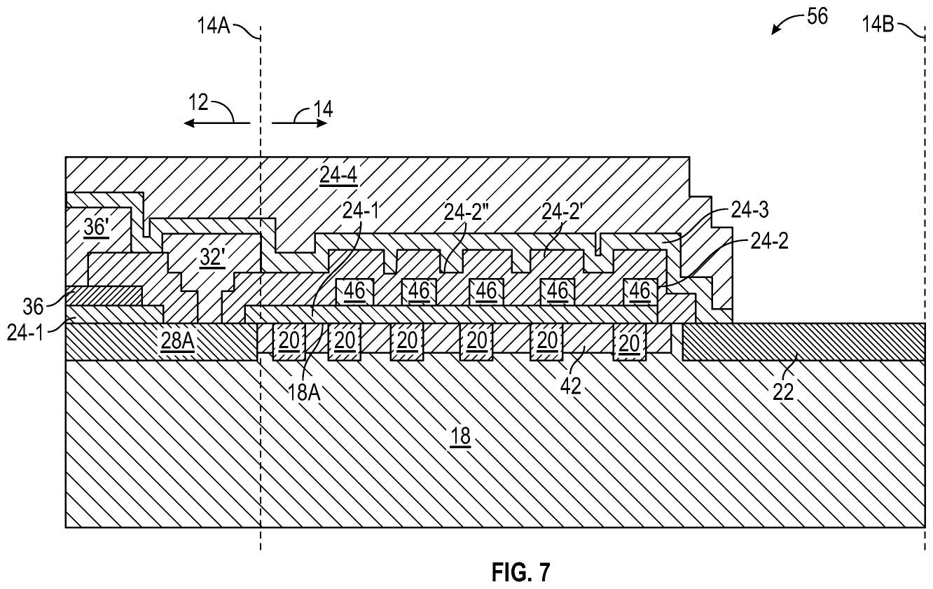

FIG. 7 is a partial cross-sectional view of a semiconductor device 56 that is similar to the semiconductor device 44 of FIG. 3, but wherein portions of the patterned layer 46 are registered with underlying guard rings 20 in a vertically offset manner. As illustrated, each discontinuous portion of the patterned layer 46 is positioned over a corresponding one of the guard rings 20 in an offset manner so that each discontinuous portion of the patterned layer 46 also extends over portions of the first passivation layer 24-1 that are adjacent to guard rings 20. Relative positions and dimensions of the patterned layer 46 may be determined to tune the electric field profile along the edge termination region 14 for improved efficiency in a similar manner as described for the field plate 54 of FIG. 6. While all portions of the patterned layer 46 are illustrated in an offset manner relative to the guard rings 20, other embodiments may include a single portion of the patterned layer 46 that is offset or multiple but not all portions of the patterned layer 46 that are offset. In this regard, portions of the patterned layer 46 may be provided as illustrated in FIG. 7 in combination with any of the arrangements of the patterned layer 46 as illustrated in any of FIG. 3, FIG. 4, FIG. 5, and FIG. 6, depending on the electric field requirements of a particular application.

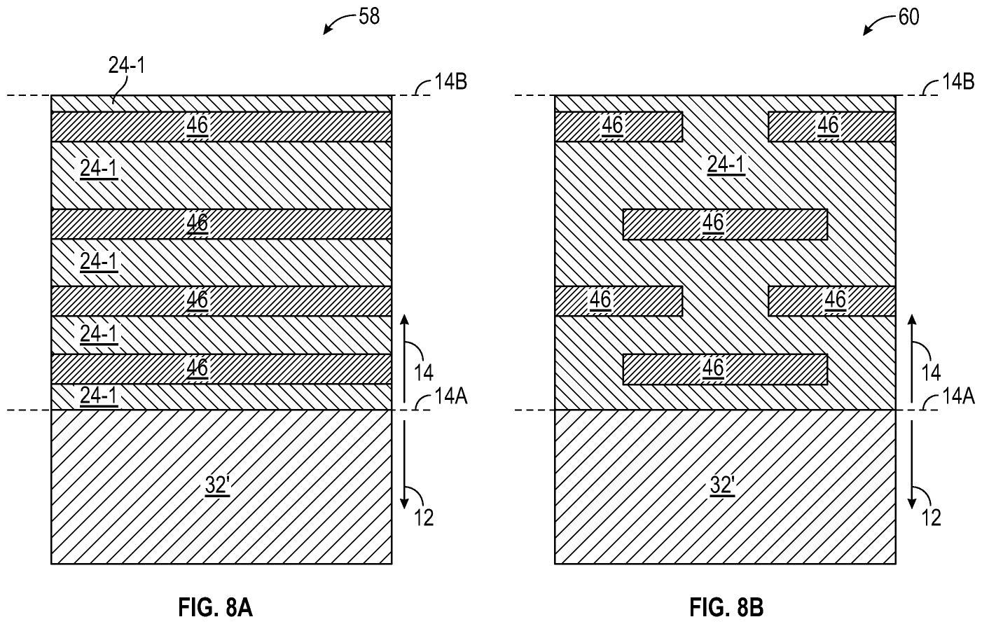

The patterned layer 46 of any of the previously described embodiments may form one or more continuous rings or one or more segmented rings around the active region 12. FIG. 8A is a top view of a portion of a semiconductor device 58 where the patterned layer 46 forms one or more continuous rings around a perimeter of the active region 12. FIG. 8B is a top view of a portion of a semiconductor device 60 where the patterned layer 46 forms one or more segmented rings around a perimeter of the active region 12. In both FIG. 8A and FIG. 8B, portions of the source interconnect 32′ are visible next to the edge termination region 14. The views provided in FIGS. 8A and 8B could be taken anywhere along peripheral edges of the edge termination region 14 as illustrated in FIG. 2B. For illustrative purposes, the second, third, and fourth passivation layers 24-2 to 24-4 are omitted to show arrangements of the patterned layer 46. Additionally, while FIGS. 8A and 8B illustrate four rings to represent principles of the present disclosure, the patterned layer 46 may form any number of rings including one or more, or five or more, or ten or more, or twenty or more, or in a range from one to twenty, or in a range from five to twenty, or in a range from ten to twenty, depending on the application.

As illustrated in FIG. 8A, the patterned layer 46 forms a series of rings that are separate from one another and each ring is continuous in the edge termination region 14. As previously described, each ring of the patterned layer 46 may form a corresponding protrusion in an overlying passivation layer and the spaces between each ring of the patterned layer 46 may form a corresponding recess in an overlying passivation layer for improved mechanical stability under thermal stress. In this regard, the protrusion that corresponds with each ring of the patterned layer 46 may also form a continuous ring protrusion around the active region 12. Accordingly, the edge termination region 14 is provided with alternating protrusions and recesses in a direction from the inside edge 14A toward the outside edge 14B.

As illustrated in FIG. 8B, the patterned layer 46 forms a series of ring segments that extend through the edge termination region 14 and around the active region 12. Rather than forming continuous rings as illustrated in FIG. 8A, the patterned layer 46 forms discontinuous or segmented rings in the edge termination region 14 and around the active region 12. In this manner, the edge termination region 14 is provided with alternating protrusions and recesses in at least two directions, for example in a first direction from the inside edge 14A toward the outside edge 14B and in a second direction that is perpendicular to the first direction. As further illustrated in FIG. 8B, the relative positions of ring segments within each segmented ring of the patterned layer 46 are laterally offset with relative positions of ring segments in adjacent segmented rings in a direction toward the outside edge 14B to further improve mechanical stability under thermal stress.

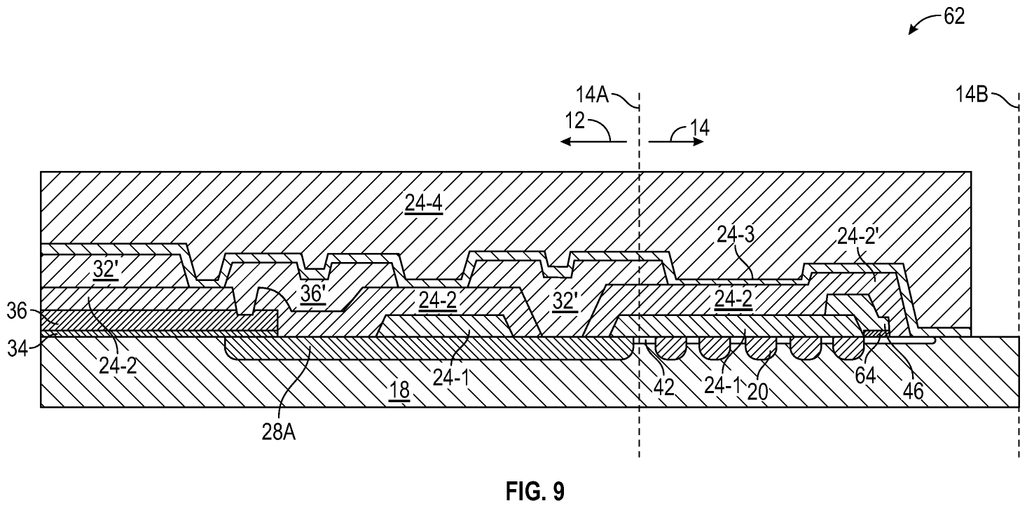

FIG. 9 is a partial cross-sectional view of a semiconductor device 62 that is similar to the semiconductor device 44 of FIG. 3, but wherein the patterned layer 46 forms a ring at a perimeter of the first passivation layer 24-1. In FIG. 9, a portion of the gate contact 36 and the gate oxide layer 34 are visible in the active region 12. In the edge termination region 14, the patterned layer 46 is provided on a top surface of the first passivation layer 24-1 and along a sidewall of the first passivation layer 24-1 that is arranged closest to the outside edge 14B of the edge termination region 14. In this manner, the patterned layer 46 may extend past and overlap the first passivation layer 24-1. In certain embodiments, the overlapped portion of the patterned layer 46 may directly contact the drift region 18 and/or the surface charge compensation region 42 of the drift region 18, when present. In other embodiments, the overlapped portion of the patterned layer 46 may be separated from the drift region 18 by an insulating layer 64. The insulating layer 64 may comprise a same material that is formed in a same fabrication step as the gate oxide layer 34, or the insulating layer 64 may comprise a different material than the gate oxide layer 34. By providing the patterned layer 46 in an overlapping manner relative to the first passivation layer 24-1, the corresponding protrusion 24-2′ of the second passivation layer 24-2 may be provided closer to the outside edge 14B for embodiments where thermal stress may be higher in this location. In certain embodiments, the patterned layer 46 of FIG. 9 may be provided in combination with any of the arrangements of the patterned layer 46 as illustrated in any of FIG. 3, FIG. 4, FIG. 5, FIG. 6, and FIG. 7, depending on the electric field requirements of a particular application. Additionally, the patterned layer 46 as illustrated in FIG. 9 may form a continuous ring or a discontinuous ring as illustrated in FIGS. 8A and 8B.

While the present disclosure provides exemplary embodiments that include MOSFETs, the principles of the present disclosure are also applicable to edge termination structures in other semiconductor devices, for example diodes, Schottky diodes, JBS diodes, PiN diodes, and IGBTs, among others. Semiconductor devices of the present disclosure may embody wide bandgap semiconductor devices, for example SiC-based devices.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A semiconductor device comprising:
a drift region;
an active region comprising a portion of the drift region;
an edge termination region in the drift region and arranged along a perimeter of the active region;
a passivation structure on the edge termination region; and
a patterned layer that is formed within the passivation structure.

2. The semiconductor device of claim 1, wherein the patterned layer is embedded within the passivation structure.

3. The semiconductor device of claim 1, wherein the patterned layer comprises polysilicon.

4. The semiconductor device of claim 1, wherein the passivation structure comprises a first passivation layer on the drift region and a second passivation layer that is on the first passivation layer.

5. The semiconductor device of claim 4, wherein the patterned layer is arranged between the first passivation layer and the second passivation layer.

6. The semiconductor device of claim 5, wherein the second passivation layer forms at least one protrusion that is registered with at least one portion of the patterned layer.

7. The semiconductor device of claim 6, wherein the passivation structure further comprises a third passivation layer that is on the second passivation layer and wherein the at least one protrusion of the second passivation layer extends into the third passivation layer.

8. The semiconductor device of claim 7, wherein the at least one protrusion comprises a plurality of protrusions and a top surface of the third passivation layer is planar in at least some portions of the passivation structure.

9. The semiconductor device of claim 8, wherein the passivation structure further comprises a fourth passivation layer that is on the third passivation layer, and the top surface of the third passivation structure forms an interface with the fourth passivation layer.

10. The semiconductor device of claim 6, wherein:
the edge termination region further comprises a plurality of guard rings in the drift region; and
the at least one portion of the patterned layer is registered with an individual guard ring of the plurality of guard rings.

11. The semiconductor device of claim 10, wherein the at least one portion of the patterned layer is registered with at least two individual guard rings of the plurality of guard rings.

12. The semiconductor device of claim 10, wherein at least one guard ring of the plurality of the guard rings is devoid of a directly overlying portion of the patterned layer.

13. The semiconductor device of claim 12, wherein the at least one guard ring of the plurality of guard rings is arranged closer to the active region than any other guard ring of the plurality of guard rings.

14. The semiconductor device of claim 10, wherein the at least one portion of the patterned layer forms a field plate in the passivation structure.

15. The semiconductor device of claim 10, wherein the at least one portion of the patterned layer is registered with the individual guard ring of the plurality of guard rings in a vertically offset position.

16. The semiconductor device of claim 4, wherein the patterned layer is arranged on the first passivation layer and the patterned layer further extends past a sidewall of the first passivation layer in a direction towards an outside edge of the edge termination region.

17. The semiconductor device of claim 1, wherein the patterned layer forms at least one continuous ring around a perimeter of the active region.

18. The semiconductor device of claim 1, wherein the patterned layer forms at least one segmented ring around a perimeter of the active region.

19. The semiconductor device of claim 18, wherein:
the at least one segmented ring comprises a first segmented ring and a second segmented ring of the patterned layer; and
ring segments of the first segmented ring are arranged in laterally offset positions relative to ring segments of the second segmented ring.

20. The semiconductor device of claim 1, wherein the drift region comprises silicon carbide (SiC).

21. The semiconductor device of claim 1, wherein the active region comprises a silicon carbide (SiC) metal-oxide-semiconductor field-effect-transistor (MOSFET).

22. A semiconductor device comprising:
a drift region;
an active region comprising a portion of the drift region;
an edge termination region in the drift region and arranged along a perimeter of the active region; and
a passivation structure on the edge termination region, wherein a passivation layer of the passivation structure forms at least one protrusion that partially extends into an additional passivation layer of the passivation structure.

23. The semiconductor device of claim 22, wherein the at least one protrusion forms at least one protrusion ring around the perimeter of the active region.

24. The semiconductor device of claim 23, wherein the at least one protrusion ring is continuous around the perimeter of the active region.

25. The semiconductor device of claim 23, wherein the at least one protrusion ring is segmented around the perimeter of the active region.

26. The semiconductor device of claim 22, wherein:
the at least one protrusion comprises a plurality of protrusions;
the passivation layer forms a plurality of recesses in between adjacent protrusions of the plurality of protrusions; and
portions of the additional passivation layer extend into each recess of the plurality of recesses.

27. The semiconductor device of claim 26, wherein at least a portion of a top surface of the additional passivation layer that is opposite the plurality of recesses is planar.

28. The semiconductor device of claim 27, wherein:
the plurality of recesses comprises a first recess and a second recess;
the first recess comprises a width that is larger than a width of the second recess; and
the first recess is arranged closer to an outside edge of the edge termination region than the second recess.

29. The semiconductor device of claim 22, further comprising a patterned layer in the passivation structure and the patterned layer is registered with the at least one protrusion.

30. The semiconductor device of claim 29, wherein the patterned layer comprises polysilicon.

31. The semiconductor device of claim 29, wherein:
the at least one protrusion comprises a plurality of protrusions; and
a discontinuous portion of the patterned layer is registered with each protrusion of the plurality of protrusions.

32. The semiconductor device of claim 29, wherein:
the edge termination region comprises a plurality of guard rings in the drift region; and
a discontinuous portion of the patterned layer is registered with an individual guard ring of the plurality of guard rings.
